(19) United States
(12) Patent Application Publication
(10) Pub. No.: US 2026/0202567 A1
(43) Pub. Date: Jul. 16, 2026

(54) ADVANCED DETECTION METHOD AND SYSTEM FOR TUNNEL BORING MACHINE BASED ON SEISMIC WAVES FROM CONTROLLABLE SEISMIC SOURCE AND ROCK BREAKING SEISMIC SOURCE

(71) Applicant: SHANDONG UNIVERSITY, Jinan (CN)

(72) Inventors: Shucai LI, Jinan (CN); Bin LIU, Jinan (CN); Xinji XU, Jinan (CN); Lei CHEN, Jinan (CN); Yuxiao REN, Jinan (CN)

(21) Appl. No.: 19/562,931

(22) Filed: Mar. 11, 2026

Related U.S. Application Data
(63) Continuation of application No. PCT/CN2023/127952, filed on Oct. 30, 2023.

(30) Foreign Application Priority Data
Sep. 11, 2023 (CN) 2023111669456

(51) Int. Cl. G01V 1/34; E21D 9/00; G01V 1/04; G01V 1/18; G01V 1/28; G01V 1/30; G06F 30/20

(52) U.S. Cl. CPC G01V 1/345; E21D 9/003; G01V 1/04; G01V 1/181; G01V 1/282; G01V 1/303; G06F 30/20; G01V 2210/324

(57) ABSTRACT

An advanced detection method for a tunnel boring machine (TBM). The method may include: preprocessing first-frequency and second-frequency seismic data from a controllable seismic source acquired during TBM stoppage, preprocessing seismic data from a rock breaking seismic source acquired during TBM tunneling; performing interferometric processing on the preprocessed seismic data with respective pilot sensor data to obtain interferometric seismic data corresponding to each of the seismic data; and utilizing a characteristic of low frequency of seismic data from the rock breaking seismic source to provide a prior constraint for inversion of the controllable seismic source, utilizing a multi-frequency property of interferometric seismic data from the controllable seismic source through frequency-division scanning to obtain a fine-grained wave velocity inversion result using multi-scale full waveform inversion, and utilizing reverse time migration imaging to obtain an imaging result for boundary characterization, thereby performing a safety TBM-driven tunnel construction based on the imaging result.

### CROSS-REFERENCE TO RELATED APPLICATIONS

The present invention claims priority to Chinese Patent Application No. 202311166945.6, entitled “ADVANCED DETECTION METHOD AND SYSTEM FOR TBM BASED ON SEISMIC WAVES FROM CONTROLLABLE SEISMIC SOURCE AND ROCK BREAKING SEISMIC SOURCE”, filed Sep. 11, 2023 with the China National Intellectual Property Administration, which is incorporated herein by reference in its entirety.

### TECHNICAL FIELD

The present invention relates to the technical field of advanced tunnel detection and, in particular, to an advanced detection method and system for a tunnel boring machine (TBM) based on seismic waves from a controllable seismic source and a rock breaking seismic source.

### BACKGROUND

The statements in this section merely provide the background related to the present invention and do not necessarily constitute prior art.

With the rapid development of tunnel engineering, tunnel boring machine (TBM) is gradually gaining widespread application. Compared to conventional drilling and blasting construction methods, TBM construction offers significant advantages such as a high degree of mechanization and fast construction speed. During the TBM-driven tunnel excavation process, adverse geological bodies pose a substantial threat to construction safety. If adverse geological conditions such as karst caves and fracture zones are encountered, disasters like machine jamming, water inrush, and mud outburst are likely to occur, potentially leading to severe consequences including casualties. Due to the complexity and particularity of the TBM-driven tunnel construction environment, advanced detection methods and technologies have consistently been a challenge in the field of advanced tunnel detection both in China and abroad.

Among the numerous in-tunnel detection methods for TBM-driven tunnels, seismic wave methods can achieve long-distance positioning and characterization of adverse geological structures and are widely used in advanced detection for TBM-driven tunnels. Detection methods can be classified into two main types based on the detection period:
(1) detection methods during TBM stoppage;
during TBM stoppage, detection methods using active sources are often employed. Conventional seismic exploration using manual hammer strikes as a seismic source is restricted by human power, resulting in short signal propagation distances. Consequently, on-board active source equipment for TBM-driven tunnels has emerged. Commonly used on-board active source detection equipment includes hydraulic seismic sources and pneumatic seismic sources. Although the excitation energy is improved, problems such as the uncontrollable resolution of effective reflected wave signals over long distances still remain.
(2) real-time detection methods during TBM tunneling;
the TBM rock-breaking seismic source utilizes vibrations generated by the TBM cutterhead breaking rocks during tunneling as the excitation source, enabling real-time detection by leveraging the characteristic of simultaneous tunneling and detection. Due to its properties of high energy and low frequency, it achieves longer detection distances. However, since the TBM rock-breaking seismic source signal lacks second-frequency information, the resolution of long-distance real-time detection methods is somewhat deficient.

### SUMMARY

To address the deficiencies of the prior art, the present invention provides an advanced detection method and system for a TBM based on seismic waves from a controllable seismic source and a rock breaking seismic source. The method and system fully utilize the two periods of TBM stoppage and construction, integrating the controllable seismic source and the rock breaking seismic source in terms of both detection procedure and detection effect. By leveraging the characteristic of the controllable seismic source to excite second-frequency signals, the method and system meet the demand for fine-grained detection during stoppage. By leveraging the real-time detection capability of the TBM rock breaking seismic source during TBM tunneling, the method and system compensate for the deficiency that the controllable seismic source can only perform detection during stoppage.

To achieve the above objectives, the following technical solutions are adopted by the present invention:

in a first aspect, the present invention provides an advanced detection method for a TBM based on seismic waves from a controllable seismic source and a rock breaking seismic source.

The advanced detection method for the TBM based on seismic waves from the controllable seismic source and the rock breaking seismic source, including the following steps:
during a TBM stoppage, acquiring two segments of seismic data with different frequencies from the controllable seismic source through frequency-division scanning, wherein the two segments of seismic data with different frequencies include a first-frequency seismic data from the controllable seismic source and a second-frequency seismic data from the controllable seismic source; and during a TBM tunneling, acquiring seismic data from the rock breaking seismic source;
preprocessing the first-frequency seismic data from the controllable seismic source and the second-frequency seismic data from the controllable seismic source acquired during the TBM stoppage, as well as the seismic data from the rock breaking seismic source acquired during the TBM tunneling;
performing cross-correlation interferometric processing on the preprocessed first-frequency seismic data from the controllable seismic source and the preprocessed second-frequency seismic data from the controllable seismic source, as well as seismic data from the rock breaking seismic source with respective pilot sensor data to obtain interferometric seismic data corresponding to each of the seismic data;
de-noising the obtained interferometric seismic data to obtain random-noise-removed interferometric seismic data, and analyzing direct wave components of the interferometric seismic data to obtain direct wave velocity data;
creating an initial velocity inversion model based on the direct wave velocity data, performing multi-scale joint inversion based on the initial velocity inversion model to obtain a final velocity inversion model, and performing reverse time migration imaging on the final velocity inversion model to obtain a final imaging result; and
by identifying the final imaging result, obtaining whether there is unfavorable geological body in front of a TBM tunnel face, and a type, characteristics, range and other information of the identified unfavorable geological body; and, according to identification results, adjusting tunneling parameters of the TBM, to control a tunneling speed of the TBM to reduce an influence of vibration on surrounding rock of the TMB tunnel, or change a tunneling direction of the TBM to avoid the identified unfavorable geological body in front of the TMB tunnel face; or, adjusting a support construction method, include adding waterproof and anti-collapse support structure or changing a relevant support construction technology, to prevent an occurrence of geological disasters.

As a further limitation of the first aspect of the present invention, the principle of the cross-correlation interferometric processing is as follows:

$$R ( t ) = {\int }_{- ∞}^{+ ∞} f ( {t}_{0} - t ) g ( {t}_{0} ) {dt}_{0} ;$$

wherein, f(t₀) and g(t₀) represent two signals; R(t) represents the interferometric seismic data generated by the cross-correlation interferometric processing; and t represents a time interval.

As an optional implementation of the first aspect of the present invention, the step of preprocessing the first-frequency seismic data from the controllable seismic source and the second-frequency seismic data from the controllable seismic source acquired during the TBM stoppage, as well as the seismic data from the rock breaking seismic source acquired during the TBM tunneling, includes:
performing de-meaning and linear de-trending processing on the first-frequency seismic data from the controllable seismic source and the second-frequency seismic data from the controllable seismic source, as well as the seismic data from the rock breaking seismic source.

As an optional implementation of the first aspect of the present invention, the step of de-noising the obtained interferometric seismic data includes:
selecting main frequency components of the seismic data using bandpass filtering and removing random noise using spectral subtraction; performing bandpass filtering using Fourier transform to extract effective signals in a frequency domain, and obtaining de-noised interferometric seismic data through inverse Fourier transform.

As an optional implementation of the first aspect of the present invention, the step of performing multi-scale joint inversion based on the initial velocity inversion model to obtain a final velocity inversion model includes:
using full waveform information of the interferometric seismic data from the rock breaking seismic source as a fitting target, performing forward modeling by applying a wavelet signal from the rock breaking seismic source to the initial velocity inversion model to obtain simulated seismic data, and using a two-norm of a difference between the simulated seismic data and the interferometric seismic data as an objective function, continuously seeking a minimum value of the objective function, thereby continuously fitting the simulated seismic data with actual interferometric seismic data to obtain a wave velocity model based on full waveform inversion of the interferometric seismic data from the rock breaking seismic source, where the acquired wave velocity model will serve as an initial model for multi-scale inversion, and due to non-uniqueness of inversion, a good initial model will contribute to improving inversion accuracy;
according to the present invention, the wave velocity model obtained based on the full waveform inversion of the interferometric seismic data from the rock breaking seismic source is used as the initial model to perform full waveform inversion of a first-frequency interferometric seismic data from the controllable seismic source obtained through frequency-division signal scanning, with autocorrelated wavelet function data of a pilot signal from the controllable seismic source serving as a seismic source, which is applied to the initial model to obtain a set of seismic data of a first-frequency signal from the controllable seismic source; with the first-frequency interferometric seismic data form the controllable seismic source used as a fitting target, and the two-norm of the difference between the simulated seismic data and the interferometric seismic data used as the objective function for inversion, based on a continuously iteratively updated stratigraphic model from the inversion, simulated seismic data increasingly approximating actual interferometric seismic data will be obtained;
when the difference between the simulated seismic data and the interferometric seismic data is small enough, or when the number of inversion iterations reaches a manually set upper limit, the full waveform inversion of the first-frequency interferometric seismic data from the controllable seismic source is considered complete, and a wave velocity model based on the full waveform inversion of the first-frequency interferometric seismic data from the controllable seismic source is obtained and, compared to the wave velocity model obtained based on the full waveform inversion of the interferometric seismic data from the rock breaking seismic source, characterizes stratigraphic structures in a more fine-grained manner; the non-linearity and cycle-skipping phenomenon in the full waveform inversion lead to multiple local minima in the objective function; the inversion of the first-frequency interferometric seismic data from the controllable seismic source through frequency-division scanning can relatively improve the robustness of the full waveform inversion process and effectively reduce the non-uniqueness of the inversion; and
with the wave velocity model based on the full waveform inversion of the first-frequency interferometric seismic data from the controllable seismic source as the initial model, full waveform inversion is performed on a second-frequency interferometric seismic data from the controllable seismic source through frequency-division scanning; autocorrelated wavelet data of a second-frequency pilot signal from the controllable seismic source serve as a seismic source and are applied to the initial velocity model obtained from the first-frequency signal inversion to obtain a set of simulated interferometric seismic data; a two-norm of a difference between the simulated interferometric seismic data and the second-frequency interferometric seismic data is used as an objective function to perform iterative optimization, yielding the final velocity inversion model; based on the second-frequency interferometric seismic data from the controllable seismic source through frequency-division scanning, due to high-frequency characteristics thereof, spurious events in the interferometric seismic data will be reduced, and information that can be fitted during inversion fitting is richer, enabling the acquisition of fine-grained structural information based on the first-frequency inversion model.

As an optional implementation of the first aspect of the present invention, pilot signals of the first-frequency seismic data and second-frequency seismic data from the controllable seismic source, as well as the seismic data from the rock breaking seismic source are respectively subjected to autocorrelation processing, to obtain wavelet signals corresponding to each of the first-frequency seismic data and second-frequency seismic data from the controllable seismic source, as well as the seismic data from the rock breaking seismic source.

As an optional implementation of the first aspect of the present invention, extracting direct wave components from the first-frequency seismic data from the controllable seismic source and the second-frequency seismic data from the controllable seismic source, as well as the seismic data from the rock breaking seismic source; surrounding rock wave velocity information is calculated and acquired using direct wave information, and the direct wave components are removed; and the initial velocity inversion model is created using the surrounding rock wave velocity information and preliminary exploration information.

As an optional implementation of the first aspect of the present invention, the step of performing reverse time migration imaging on the final velocity inversion model to obtain a final imaging result includes:
applying autocorrelated wavelet data of a pilot signal from the rock breaking seismic source at a position of a rock breaking seismic source pilot sensor, applying the interferometric seismic data from the rock breaking seismic source in reverse time at geophone positions, saving wavefields of both, and obtaining a imaging result from the rock breaking seismic source through correlation stacking;
applying autocorrelated wavelet data of the second-frequency pilot signal from the controllable seismic source at a position of a controllable seismic source pilot sensor, applying the second-frequency interferometric seismic data from the controllable seismic source in reverse time at the geophone positions, saving wavefields of both, and obtaining a second-frequency imaging result from the controllable seismic source through correlation stacking;
applying autocorrelated wavelet data of a first-frequency pilot signal from the controllable seismic source at the position of the controllable seismic source pilot sensor, applying the first-frequency interferometric seismic data from the controllable seismic source in reverse time at the geophone positions, saving wavefields of both, and obtaining a first-frequency imaging result from the controllable seismic source through correlation stacking;
obtaining a final imaging result by stacking the imaging result from the rock breaking seismic source, the second-frequency imaging result from the controllable seismic source, and the first-frequency imaging result from the controllable seismic source; and
by identifying the final imaging result, obtaining whether there is unfavorable geological body in front of a TBM tunnel face, and a type, characteristics, range and other information of the identified unfavorable geological body; and, according to identification results, adjusting tunneling parameters of the TBM, to control a tunneling speed of the TBM to reduce an influence of vibration on surrounding rock of the TMB tunnel, or change a tunneling direction of the TBM to avoid the identified unfavorable geological body in front of the TMB tunnel face; or, adjusting a support construction method, include adding waterproof and anti-collapse support structure or changing a relevant support construction technology, to prevent an occurrence of geological disasters.

In a second aspect, the present invention provides an advanced detection system for a TBM based on seismic waves from a controllable seismic source and a rock breaking seismic source.

The advanced detection system for a TBM based on seismic waves from a controllable seismic source and a rock breaking seismic source includes:
a preprocessing module, configured to: preprocess a first-frequency seismic data from the controllable seismic source and a second-frequency seismic data from the controllable seismic source acquired after a TBM stoppage, as well as seismic data from the rock breaking seismic source acquired during a TBM tunneling;
an interferometric processing module, configured to: perform interferometric processing on the preprocessed first-frequency seismic data from the controllable seismic source and second-frequency seismic data from the controllable seismic source, as well as the seismic data from the rock breaking seismic source with respective pilot sensor data to obtain interferometric seismic data corresponding to each of the seismic data;
an initial inversion model construction module, configured to: de-noise (through bandpass filtering and spectral subtraction) the obtained interferometric seismic data according to a first-frequency interferometric seismic data from the controllable seismic source and a second-frequency interferometric seismic data from the controllable seismic source, as well as an interferometric seismic data from the rock breaking seismic source to obtain random-noise-removed interferometric seismic data, thereby obtaining direct wave velocity data of the interferometric seismic data, and create an initial velocity inversion model based on the direct wave velocity data; and
a multi-scale inversion imaging module, configured to: perform multi-scale joint inversion based on the initial velocity inversion model to obtain a final velocity inversion model, and perform reverse time migration imaging on the final velocity inversion model to obtain a final imaging result;
by identifying the final imaging result, obtaining whether there is unfavorable geological body in front of a TBM tunnel face, and a type, characteristics, range and other information of the identified unfavorable geological body; and, according to identification results, adjusting tunneling parameters of the TBM, to control a tunneling speed of the TBM to reduce an influence of vibration on surrounding rock of the TMB tunnel, or change a tunneling direction of the TBM to avoid the identified unfavorable geological body in front of the TMB tunnel face; or, adjusting a support construction method, include adding waterproof and anti-collapse support structure or changing a relevant support construction technology, to prevent an occurrence of geological disasters.

In a third aspect, the present invention provides an advanced detection system for a TBM based on seismic waves from a controllable seismic source and a rock breaking seismic source.

The advanced detection system for a TBM based on seismic waves from a controllable seismic source and a rock breaking seismic source includes:
an electromagnetic controllable seismic source, three-component geophones, a controllable seismic source pilot sensor, and a rock breaking seismic source pilot sensor, wherein,
the electromagnetic controllable seismic source is fixed on a gripper shoe of the TBM, the three-component geophones are fixed on both sides of a TBM working platform, the controllable seismic source pilot sensor is fixed on a rock wall near the electromagnetic controllable seismic source, and the rock breaking seismic source pilot sensor is located at a rear side of a TBM cutterhead;
the electromagnetic controllable seismic source includes: an airbag, a blocking plate, a counterweight housing, a base plate, guide rails, a moving assembly, an acceleration sensor, and an excitation assembly;
the guide rails are disposed on the base plate, the counterweight housing is slidably connected to the guide rails via the moving assembly, the excitation assembly and the acceleration sensor are fixed on one side of the counterweight housing, the blocking plate is fixed on the base plate on the other side of the counterweight housing, and the airbag is fixed on a side of the blocking plate facing the counterweight housing; and
the system further includes a main control unit in communication with the electromagnetic controllable seismic source, the three-component geophones, the controllable seismic source pilot sensor, and the rock breaking seismic source pilot sensor, respectively, where the main control unit is configured to perform detection using the advanced detection method for a TBM based on seismic waves from a controllable seismic source and a rock breaking seismic source according to any one of the foregoing aspects.

As an optional implementation of the third aspect of the present invention, the three-component geophones and the controllable seismic source pilot sensor, upon detecting excitation by the electromagnetic controllable seismic source, are activated and begin receiving seismic data; and when the excitation by the electromagnetic controllable seismic source ends, the three-component geophones stop working and save the seismic data to the main control unit.

As an optional implementation of the third aspect of the present invention, during TBM tunneling, the main control unit controls the rock breaking seismic source pilot sensor and the three-component geophones to be activated simultaneously to receive seismic data; and when the detection ends, the main control unit controls the rock breaking seismic source pilot sensor and the three-component geophones to stop simultaneously and saves the seismic data to the main control unit.

Compared with the prior art, the present invention has the following beneficial effects:

1. in response to the complexity and particularity of the tunnel detection environment, the present invention innovatively proposes an advanced detection system for a TBM based on seismic waves from a controllable seismic source and a rock breaking seismic source, which fully utilizes the two periods of TBM stoppage and construction and integrates the controllable seismic source and the rock breaking seismic source in terms of both detection procedure and detection effect, thereby overcoming the limitations of conventional detection methods, such as reliance on single detection methods and insufficient detection accuracy and coverage.

2. The present invention innovatively proposes a data processing method for controllable seismic sources and rock breaking seismic sources, which performs preliminary de-noising through bandpass filtering and removes random noise using cross-correlation methods to obtain interferometric seismic data, providing a data foundation for subsequent inversion and imaging.

3. The present invention innovatively proposes a joint inversion and imaging method for controllable seismic sources and rock breaking seismic sources: a first full waveform inversion is performed on an initial model using lower-frequency (first-frequency) interferometric seismic data from the rock breaking seismic source to obtain a large-scale inversion result, which is then used as an initial model for a second full waveform inversion using higher-frequency (second-frequency) interferometric seismic data from the controllable seismic source, yielding a more fine-grained velocity inversion model. By comprehensively utilizing two sets of interferometric seismic data, structural information is further obtained through reverse time migration imaging, significantly improving the accuracy of inversion imaging. Through the combined application of the rock breaking seismic source and the controllable seismic source with low and high-frequency characteristics, the objective of fine-grained detection in TBM-driven tunnels is achieved.

Advantages of additional aspects of the present invention will be provided in part in the following description, and will become apparent in part from the following description, or may be learned through practice of the present invention.

### BRIEF DESCRIPTION OF THE DRAWINGS

The accompanying drawings as a part of the present invention are provided to further illustrate the present invention. The exemplary examples of the present invention and their descriptions are intended to explain the present invention and do not constitute an undue limitation thereon.

FIG. 1 is a front view of an electromagnetic controllable seismic source provided in Example 1 of the present invention;

FIG. 2 is a top view of the electromagnetic controllable seismic source provided in Example 1 of the present invention;

FIG. 3 is a schematic view of an advanced detection system for a TBM based on seismic waves from a controllable seismic source and a rock breaking seismic source provided in Example 1 of the present invention; and

FIG. 4 is a schematic flowchart of an advanced detection method for a TBM based on seismic waves from a controllable seismic source and a rock breaking seismic source provided in Example 2 of the present invention;

wherein: 1, excitation assembly; 2, acceleration sensor; 3, guide rail; 4, moving assembly; 5, counterweight housing; 6, base plate; 7, airbag; 8, blocking plate; 9, TBM cutterhead; 10, rock breaking seismic source pilot sensor; 11, gripper shoe; 12, electromagnetic controllable seismic source; 13, three-component geophone; 14, working platform; 15, controllable seismic source pilot sensor; and, 16, mounting hole.

### DETAILED DESCRIPTION

The present invention will be further described with reference to the accompanying drawings and examples.

It should be noted that the following detailed description is exemplary and aims to further describe the present invention. Unless otherwise specified, all technical and scientific terms used herein have the same meanings as those generally understood by a person of ordinary skill in the art to which the present invention belongs.

The examples of the present invention and the features in the examples can be combined with each other in case of no conflict.

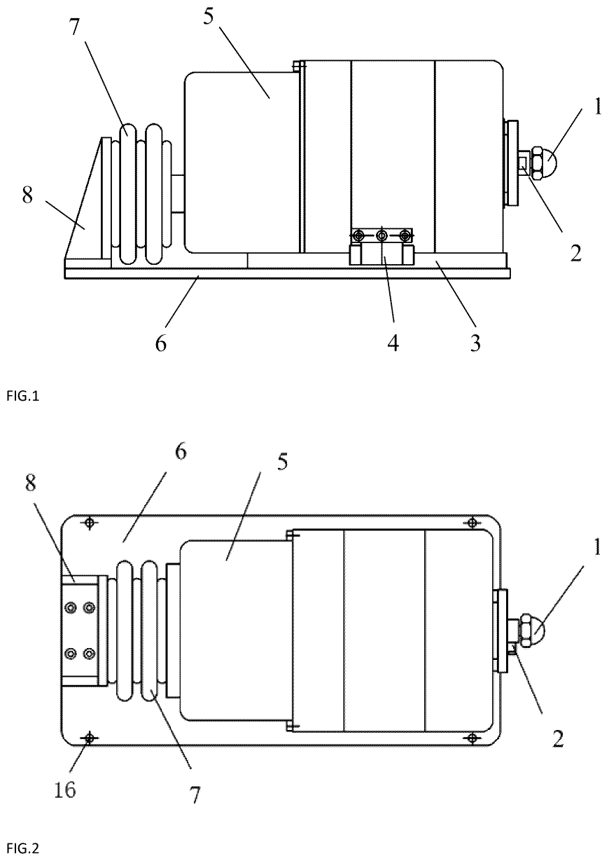

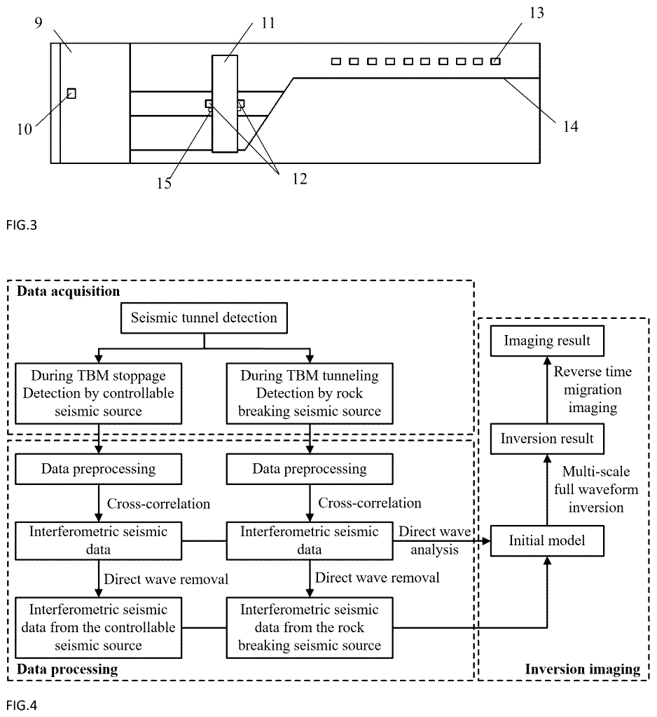

The present example of the present invention provides an advanced detection system for a TBM based on seismic waves from a controllable seismic source and a rock breaking seismic source. As shown in FIGS. 1, 2, and 3, the system includes:
an electromagnetic controllable seismic source 12, three-component geophones 13, a controllable seismic source pilot sensor 15, and a rock breaking seismic source pilot sensor 10, wherein:
the electromagnetic controllable seismic source 12 is fixed on a gripper shoe 11 of the TBM, the three-component geophones 13 are fixed on both sides of a TBM working platform 14, the controllable seismic source pilot sensor 15 is fixed on a rock wall near the electromagnetic controllable seismic source 12 (specifically, the controllable seismic source pilot sensor 15 is fixed separately on the rock wall, detached from the TBM, and positioned close to the electromagnetic controllable seismic source 12), and the rock breaking seismic source pilot sensor 10 is located at a rear side of a TBM cutterhead 9;
the electromagnetic controllable seismic source 12 includes: an airbag 7, a blocking plate 8, a counterweight housing 5, a base plate 6, guide rails 3, a moving assembly 4, an acceleration sensor 2, and an excitation assembly 1;
the guide rails 3 are disposed on the base plate 6, the counterweight housing 5 is slidably connected to the guide rails 3 via the moving assembly 4, the excitation assembly 1 and the acceleration sensor 2 are fixed on one side of the counterweight housing 5, the blocking plate 8 is fixed on the base plate 6 on the other side of the counterweight housing 5, the airbag 7 is fixed on a side of the blocking plate 8 facing the counterweight housing 5, and the base plate 6 is fixedly connected to the gripper shoe 11 via mounting holes 16; and
the system further includes a main control unit in communication with the electromagnetic controllable seismic source 12, the three-component geophones 13, the controllable seismic source pilot sensor 15, and the rock breaking seismic source pilot sensor 10, respectively, where the main control unit performs detection control and data analysis based on acquired data.

Specifically, the working method includes:
S1: during TBM stoppage, controlling, by a host (i.e., the main control unit) in a main control room, excitation parameters of the electromagnetic controllable seismic source 12, including excitation duration, waveform, and excitation force, wherein:
the airbag 7 of the electromagnetic controllable seismic source 12 installed on the gripper shoe 11 is inflated to ensure buffering during impact, the excitation assembly 1 extends and presses firmly against the rock wall, and the counterweight housing 5 is moved back and forth by controlling a moving coil inside the controllable seismic source to achieve the purpose of excitation;
the three-component geophones 13 on both sides of the TBM working platform 14 and the pilot sensor 15 on the rock wall near the controllable seismic source 12, upon detecting excitation by the electromagnetic controllable seismic source 12, are activated and begin receiving seismic data;
the acceleration sensor 2 at the front end of the electromagnetic controllable seismic source 12 can form closed-loop control, precisely controlling the excitation duration, waveform, and excitation force of the controllable seismic source; and
the electromagnetic controllable seismic source 12 performs frequency-division signal scanning to acquire two sets of signals: a first-frequency signal and a second-frequency signal (preferably, in the present example, the bands of the first-frequency and second-frequency are relative concepts, for example, a range of the band of the first-frequency may be 10-200 Hz and a range of the band of the second-frequency may be 200-400 Hz, at this time, the “first-frequency” band may be called as a low-frequency band, and the “second-frequency” band is called as a high-frequency band; alternatively, the range of the band of the first-frequency may be 100-300 Hz and the range of the band of the second-frequency may be 300-400 Hz, at this time, the “first-frequency” band may also be called as the low-frequency band, and the “second-frequency” band is called as the high-frequency band; and the ranges of the bands of the first- and second-frequencies may also overlap, which will not be elaborated herein), and when the excitation of the controllable seismic source 12 ends, the three-component geophones 13 stop working and save the seismic data to the host in the main control room;
S2: during TBM tunneling, controlling, by the host in the main control room, the pilot sensor 10 installed at the rear side of the cutterhead 9 and the three-component geophones 13 to be activated simultaneously to receive seismic data; and
when the detection ends, controlling the pilot sensor 10 and the three-component geophones 13 to stop simultaneously, and saving the seismic data to the host in the main control room.

### Example 2

As shown in FIG. 4, the present example of the present invention provides an advanced detection method for a TBM based on seismic waves from a controllable seismic source and a rock breaking seismic source, including the following steps:
S1: data processing
S1.1: preprocessing original data
performing de-meaning and linear de-trending processing on seismic data from the rock breaking seismic source and a first-frequency seismic data from the controllable seismic source and a second-frequency seismic data from the controllable seismic source;
S1.2: performing interferometric processing on the seismic data from the rock breaking seismic source and the seismic data of the two frequency bands from the controllable seismic source respectively, and performing analysis to obtain direct wave velocity data;
wherein, cross-correlation between the seismic data and pilot sensor signals is calculated by the following formula:

$$R ( t ) = {\int }_{- ∞}^{+ ∞} f ( {t}_{0} - t ) g ( {t}_{0} ) {dt}_{0} ; \qquad ( 1 )$$

wherein, f(t₀) and g(t₀) represent two signals; R(t) represents interferometric seismic data generated by the cross-correlation interferometric processing; f(⋅) represents the seismic data; g(⋅) represents signals received by the pilot sensors, which must correspond to the components of the seismic data; t₀ represents an integration variable for integration over all time; and t represents an independent variable of a function R(t), used to calculate cross-correlation values at different times.

By interferometric processing, random noise can be removed and interferometric seismic data can be obtained. The pilot signal from the rock breaking seismic source and the first-frequency and second-frequency pilot signals from the controllable seismic source are subjected to autocorrelation processing respectively to obtain their respective wavelet signals (autocorrelation processing is a type of cross-correlation processing and can also be calculated by formula (1), where the two signals f and g are the same signal).
S1.3: de-noising the interferometric seismic data through bandpass filtering and spectral subtraction, where the bandpass filtering extracts dominant frequency information using a bandpass method via Fourier transform, and then converts back to seismic data via inverse Fourier transform:

$$F ( ω ) = {\int }_{- ∞}^{+ ∞} f ( t ) {e}^{- j ω t} dt ; \qquad ( 2 )$$

$$f ( t ) = \frac{1}{2 π} {\int }_{- ∞}^{+ ∞} F ( ω ) {e}^{j ω t} d ω ; \qquad ( 3 )$$

wherein, f(t) represents seismic data in a time domain; and F(ω) represents seismic data in a frequency domain. The above processing enables preliminary de-noising of both the seismic data from the rock breaking seismic source and the seismic data from the controllable seismic source.
S2: multi-scale joint inversion
S2.1: using the wave velocity model obtained from the data processing step as an initial model, and waveform and arrival time (signal arrival time) of the interferometric seismic data from the rock breaking seismic source as fitting targets, performing forward modeling by applying a wavelet signal from the rock breaking seismic source to the wave velocity model to obtain simulated seismic data, and continuously fitting the simulated seismic data with actual interferometric seismic data:

$$E = {‖ {d}_{obs} - {d}_{mod} ‖}^{2} ; \qquad ( 4 )$$

wherein, E represents an error; d_{obs} represents observed seismic data; and d_{mod} represents the seismic data obtained through the forward modeling;
leveraging the first-frequency property of the seismic data from the rock breaking seismic source, a large-scale inversion result is obtained to provide a prior constraint for fine-grained inversion of the controllable seismic source.
S2.2: using the wave velocity model obtained based on the full waveform inversion of the interferometric seismic data from the rock breaking seismic source as an initial model, a first-frequency interferometric seismic data from the controllable seismic source as fitting targets, and autocorrelated wavelet data of a pilot signal from the controllable seismic source as a seismic source, performing full waveform inversion on the first-frequency interferometric seismic data from the controllable seismic source, and repeating the inversion process of S2.1;
by using the first-frequency interferometric seismic data from the controllable seismic source in conjunction with the rock breaking seismic source, the large-scale structure is further delineated, providing supplementary inversion data for distant geological structures. This reduces the non-uniqueness associated with using the rock breaking seismic source alone for inversion and provides a better initial model for subsequent fine-grained inversion.
S2.3: performing further inversion on the wave velocity model obtained in S2.2 using a second-frequency interferometric seismic data from the controllable seismic source. Since the second-frequency seismic data can better characterize detailed structures, this achieves the objective of fine-grained detection.

Through multiple joint inversions using the seismic data from the rock breaking seismic source and the first-frequency seismic data and second-frequency seismic data from the controllable seismic source, the inversion results gradually progress from outlining large-scale structures to characterizing detailed structures. This joint inversion method, which integrates the three types of seismic data, can improve the accuracy and precision of the inversion while reducing the problem of non-uniqueness.
S3: reverse time migration imaging
based on the velocity inversion model obtained in S2.3, the autocorrelated wavelet data of the pilot signal from the rock breaking seismic source are used as a seismic source signal for forward propagation, which is applied at the position of the rock breaking seismic source pilot sensor; and the interferometric seismic data from the rock breaking seismic source are used as a seismic source signal for backward propagation, which is applied in reverse time at the geophone positions. The wavefields of both are saved, and the rock breaking seismic source imaging result is obtained through correlation stacking.

The wavefield cross-correlation result is calculated by the following formula:

$$I ( x , y , z ) = {\int }_{0}^{T} S ( x , y , z , t ) \cdot R ( x , y , z , t ) dt ; \qquad ( 5 )$$

wherein, I(x,y,z) represents the imaging result; S(x,y,z,t) represents the seismic source wavefield data; R(x,y,z,t) represents the geophone wavefield data; T represents the total duration; (x,y,z) represents the three-dimensional coordinates of the seismic source wave; and t represents the time.

The same imaging method used for the rock breaking seismic source is applied to the seismic data of the two frequency bands from the controllable seismic source to obtain a controllable seismic source imaging result, and the obtained imaging result is then stacked to obtain the final imaging result.

### Example 3

The present example of the present invention provides an advanced detection system for a TBM based on seismic waves from a controllable seismic source and a rock breaking seismic source, including:
a preprocessing module, configured to: preprocess a first-frequency seismic data from the controllable seismic source and a second-frequency seismic data from the controllable seismic source acquired after a TBM stoppage, as well as seismic data acquired from the rock breaking seismic source during a TBM tunneling;
an interferometric processing module, configured to: perform interferometric processing on the preprocessed first-frequency seismic data from the controllable seismic source and second-frequency seismic data from the controllable seismic source, as well as seismic data from the rock breaking seismic source with respective pilot sensor data to obtain interferometric seismic data corresponding to each of the seismic data;
an initial inversion model construction module, configured to: de-noise the obtained interferometric seismic data according to a first-frequency interferometric seismic data from the controllable seismic source and a second-frequency interferometric seismic data from the controllable seismic source, as well as a interferometric seismic data from the rock breaking seismic source to obtain random-noise-removed interferometric seismic data, thereby obtaining direct wave velocity data of the interferometric seismic data, and create an initial velocity inversion model based on the direct wave velocity data; and
a multi-scale inversion imaging module, configured to: perform multi-scale joint inversion based on the initial velocity inversion model to obtain a final velocity inversion model, and perform reverse time migration imaging on the final velocity inversion model to obtain a final imaging result;
by identifying the final imaging result, obtaining whether there is unfavorable geological body in front of a TBM tunnel face, and a type, characteristics, range and other information of the identified unfavorable geological body; and, according to identification results, adjusting tunneling parameters of the TBM, to control a tunneling speed of the TBM to reduce an influence of vibration on surrounding rock of the TMB tunnel, or change a tunneling direction of the TBM to avoid the identified unfavorable geological body in front of the TMB tunnel face; or, adjusting a support construction method, include adding waterproof and anti-collapse support structure or changing a relevant support construction technology, to prevent an occurrence of geological disasters.

The working method of the system is the same as the advanced detection method for a TBM based on seismic waves from a controllable seismic source and a rock breaking seismic source provided in Example 2, and will not be elaborated herein.

The foregoing is merely illustrative of the exemplary examples of the present invention and is not intended to limit the present invention. For those skilled in the art, the present invention may have various modifications and changes. Any modifications, equivalent replacements, and improvements made within the spirit and principle of the present invention shall fall within the scope of protection of the present invention.

1. An advanced detection method for a tunnel boring machine (TBM) based on seismic waves from a controllable seismic source and a rock breaking seismic source, comprising the following steps:
preprocessing low-frequency seismic data and high-frequency seismic data acquired from the controllable seismic source during TBM stoppage, as well as seismic data acquired from the rock breaking seismic source during TBM tunneling;
performing interferometric processing on the preprocessed low-frequency seismic data and high-frequency seismic data from the controllable seismic source, as well as seismic data from the rock breaking seismic source with respective pilot sensor data to obtain interferometric seismic data corresponding to each of the seismic data;
de-noising the obtained interferometric seismic data according to the low-frequency interferometric seismic data and high-frequency interferometric seismic data from the controllable seismic source, as well as the interferometric seismic data from the rock breaking seismic source to obtain random-noise-removed interferometric seismic data, thereby obtaining direct wave velocity data of the interferometric seismic data, and creating an initial velocity inversion model based on the direct wave velocity data; and
performing multi-scale joint inversion based on the initial velocity inversion model to obtain a final velocity inversion model, and performing reverse time migration imaging on the final velocity inversion model to obtain a final imaging result.

2. The advanced detection method for the TBM based on seismic waves from the controllable seismic source and the rock breaking seismic source according to claim 1, wherein the low-frequency seismic data and high-frequency seismic data acquired from the controllable seismic source during TBM stoppage as well as the seismic data acquired from the rock breaking seismic source during TBM tunneling are subjected to de-noising, comprising:
de-noising, through bandpass filtering and spectral subtraction, the low-frequency seismic data and high-frequency seismic data from the controllable seismic source, as well as the seismic data from the rock breaking seismic source, wherein the bandpass filtering extracts dominant frequency information in a frequency domain via Fourier transform, followed by inverse Fourier transform to convert back to seismic data.

3. The advanced detection method for the TBM based on seismic waves from the controllable seismic source and the rock breaking seismic source according to claim 1, wherein
the step of performing multi-scale joint inversion based on the initial velocity inversion model to obtain a final velocity inversion model comprises:
using waveform and arrival time of the interferometric seismic data from the rock breaking seismic source as fitting targets, performing forward modeling by applying a wavelet signal from the rock breaking seismic source to the initial velocity inversion model to obtain simulated seismic data, and continuously fitting the simulated seismic data with actual interferometric seismic data to obtain a wave velocity model based on full waveform inversion of the interferometric seismic data from the rock breaking seismic source;
using the wave velocity model obtained based on the full waveform inversion of the interferometric seismic data from the rock breaking seismic source as an initial model, the low-frequency interferometric seismic data from the controllable seismic source as fitting targets, and autocorrelated wavelet data of a pilot signal from the controllable seismic source as a seismic source, performing full waveform inversion on the low-frequency interferometric seismic data from the controllable seismic source, to obtain a wave velocity model based on the full waveform inversion of the low-frequency interferometric seismic data from the controllable seismic source; and
using the wave velocity model based on the full waveform inversion of the low-frequency interferometric seismic data from the controllable seismic source as an initial model, the high-frequency interferometric seismic data from the controllable seismic source as fitting targets, and the autocorrelated wavelet data of the pilot signal from the controllable seismic source as the seismic source, performing full waveform inversion on the high-frequency interferometric seismic data from the controllable seismic source, to obtain a final wave velocity inversion model.

4. The advanced detection method for the TBM based on seismic waves from the controllable seismic source and the rock breaking seismic source according to claim 1, wherein pilot signals of the low-frequency seismic data and high-frequency seismic data from the controllable seismic source, as well as the seismic data from the rock breaking seismic source are respectively subjected to autocorrelation processing, to obtain wavelet signals corresponding to each of the low-frequency seismic data and high-frequency seismic data from the controllable seismic source, as well as the seismic data from the rock breaking seismic source.

5. The advanced detection method for the TBM based on seismic waves from the controllable seismic source and the rock breaking seismic source according to claim 1, wherein direct wave components are extracted from the low-frequency seismic data and high-frequency seismic data from the controllable seismic source, as well as the seismic data from the rock breaking seismic source; surrounding rock wave velocity information is calculated and acquired using direct wave information, and the direct wave components are removed; and the initial velocity inversion model is created using the surrounding rock wave velocity information and preliminary exploration information.

6. The advanced detection method for the TBM based on seismic waves from the controllable seismic source and the rock breaking seismic source according to claim 1, wherein
the step of performing reverse time migration imaging on the final velocity inversion model to obtain a final imaging result comprises:
applying autocorrelated wavelet data of a pilot signal from the rock breaking seismic source at a position of a rock breaking seismic source pilot sensor, applying the interferometric seismic data from the rock breaking seismic source in reverse time at geophone positions, saving wavefields of both, and obtaining a rock breaking seismic source imaging result through correlation stacking;
applying autocorrelated wavelet data of a high-frequency pilot signal from the controllable seismic source at a position of a controllable seismic source pilot sensor, applying the high-frequency interferometric seismic data from the controllable seismic source in reverse time at the geophone positions, saving wavefields of both, and obtaining a high-frequency controllable seismic source imaging result through correlation stacking;
applying autocorrelated wavelet data of a low-frequency pilot signal from the controllable seismic source at the position of the controllable seismic source pilot sensor, applying the low-frequency interferometric seismic data from the controllable seismic source in reverse time at the geophone positions, saving wavefields of both, and obtaining a low-frequency controllable seismic source imaging result through correlation stacking; and
obtaining the final imaging result by stacking the rock breaking seismic source imaging result, the high-frequency controllable seismic source imaging result, and the low-frequency controllable seismic source imaging result.

7. An advanced detection system for a tunnel boring machine (TBM) based on seismic waves from a controllable seismic source and a rock breaking seismic source, comprising:
a preprocessing module, configured to: preprocess a low-frequency seismic data and a high-frequency seismic data from the controllable seismic source acquired after a TBM stoppage, as well as seismic data from the rock breaking seismic source acquired during a TBM tunneling;
an interferometric processing module, configured to: perform interferometric processing on the preprocessed low-frequency seismic data and high-frequency seismic data from the controllable seismic source, as well as seismic data from the rock breaking seismic source with respective pilot sensor data to obtain interferometric seismic data corresponding to each of the seismic data;
an initial inversion model construction module, configured to: de-noise the obtained interferometric seismic data according to a low-frequency interferometric seismic data and a high-frequency interferometric seismic data from the controllable seismic source, as well as an interferometric seismic data from the rock breaking seismic source to obtain random-noise-removed interferometric seismic data, thereby obtaining direct wave velocity data of the interferometric seismic data, and create an initial velocity inversion model based on the direct wave velocity data; and
a multi-scale inversion imaging module, configured to: perform multi-scale joint inversion based on the initial velocity inversion model to obtain a final velocity inversion model, and perform reverse time migration imaging on the final velocity inversion model to obtain a final imaging result.

8. An advanced detection system for a tunnel boring machine (TBM) based on seismic waves from a controllable seismic source and a rock breaking seismic source, comprising:
an electromagnetic controllable seismic source, three-component geophones, a controllable seismic source pilot sensor, and a rock breaking seismic source pilot sensor, wherein the electromagnetic controllable seismic source is fixed on a gripper shoe of the TBM, the three-component geophones are fixed on both sides of a TBM working platform, the controllable seismic source pilot sensor is fixed on a rock wall near the electromagnetic controllable seismic source, and the rock breaking seismic source pilot sensor is located at a rear side of a TBM cutterhead;
the electromagnetic controllable seismic source comprises: an airbag, a blocking plate, a counterweight housing, a base plate, guide rails, a moving assembly, an acceleration sensor, and an excitation assembly;
the guide rails are disposed on the base plate, the counterweight housing is slidably connected to the guide rails via the moving assembly, the excitation assembly and the acceleration sensor are fixed on one side of the counterweight housing, the blocking plate is fixed on the base plate on the other side of the counterweight housing, and the airbag is fixed on a side of the blocking plate facing the counterweight housing; and
the system further comprises a main control unit in communication with the electromagnetic controllable seismic source, the three-component geophones, the controllable seismic source pilot sensor, and the rock breaking seismic source pilot sensor, respectively;
wherein, the main control unit is configured to perform the advanced detection method for the TBM based on seismic waves from the controllable seismic source and the rock breaking seismic source according to claim 1.

9. The advanced detection system for the TBM based on seismic waves from the controllable seismic source and the rock breaking seismic source according to claim 8, wherein
the three-component geophones and the controllable seismic source pilot sensor, upon detecting excitation by the electromagnetic controllable seismic source, are activated and begin receiving seismic data; and when the excitation by the electromagnetic controllable seismic source ends, the three-component geophones stop working and save the seismic data to the main control unit.

10. The advanced detection system for the TBM based on seismic waves from the controllable seismic source and the rock breaking seismic source according to claim 8, wherein
during a TBM tunneling, the main control unit controls the rock breaking seismic source pilot sensor and the three-component geophones to be activated simultaneously to receive seismic data; and when the detection ends, the main control unit controls the rock breaking seismic source pilot sensor and the three-component geophones to stop simultaneously and saves the seismic data to the main control unit.
